(19) United States
(12) Patent Application Publication
(10) Pub. No.: US 2025/0211212 A1
(43) Pub. Date: Jun. 26, 2025

(54) DUTY CYCLE REGULATOR

(71) Applicant: Intel Corporation, Santa Clara, CA (US)

(72) Inventors: Mark L. Neidengard, Beaverton, OR (US); Tejas Tapsale, Beaverton, OR (US); Vaughn J. Grossnickle, Beaverton, OR (US)

(21) Appl. No.: 18/394,910

(22) Filed: Dec. 22, 2023

(51) Int. Cl. H03K 3/037; H03K 3/012; H03K 5/133; H03K 5/156

(52) U.S. Cl. CPC H03K 3/0375; H03K 3/012; H03K 5/133; H03K 5/1565

(57) ABSTRACT

Embodiments herein relate to a duty cycle evaluation circuit which includes a finite state machine (FSM), a logic circuit coupled to the FSM, a tunable delay circuit having an input coupled to an output of the logic circuit, a flip-flop having clock input coupled to the input of the tunable delay circuit and a data input coupled to an output of the tunable delay circuit, a first sampling circuit having a data input coupled to a data output of the flip-flop, a data output coupled to the FSM and a clock input coupled to the FSM, and a second sampling circuit having a data input coupled to the data output of the flip-flop, a data output coupled to the FSM and a clock input coupled to the FSM.

### BACKGROUND

Computing devices rely on periodic signals such as clock signals to operate. A clock signal is a periodic waveform used in digital circuits to synchronize the operations of various components. It serves as a timing reference that dictates when specific operations should occur, helping to coordinate the flow of data and control signals. One example of a clock signal is a pulse-width modulation (PWM) signal. A PWM signal alternates between high and low levels according to a duty cycle. However, various challenges are encountered in ensuring that the duty cycle is accurate.

### BRIEF DESCRIPTION OF THE DRAWINGS

The embodiments of the disclosure will be understood more fully from the detailed description given below and from the accompanying drawings of various embodiments of the disclosure, which, however, should not be taken to limit the disclosure to the specific embodiments, but are for explanation and understanding only.

FIG. 1 depicts an example duty cycle evaluation circuit 100, in accordance with various embodiments.

FIG. 2A depicts another example duty cycle evaluation circuit 200, in accordance with various embodiments.

FIG. 2B depicts example plots which explain the operation of the sideload 228 of FIG. 2A, in accordance with various embodiments.

FIG. 3 depicts example plots of signals in the circuit 200 of FIG. 2A when a clock signal has a duty cycle of 50%, when the sideload 228 is not used, in accordance with various embodiments.

FIG. 4 depicts example plots of signals in the circuit 200 of FIG. 2A when a clock signal has a duty cycle of 50%, when the sideload 228 is used, in accordance with various embodiments.

FIG. 5 depicts an example set of plots 500 indicating a duty cycle self-error versus voltage, in accordance with various embodiments.

FIG. 6A depicts a flowchart of an example process for operating a duty cycle evaluation circuit, consistent with the circuit 200 of FIG. 2A, in accordance with various embodiments.

FIG. 6B depicts a flowchart of an example implementation of the inner control loop of FIG. 6A, in accordance with various embodiments.

FIG. 7A depicts an example plot of delay versus time for the tunable delay circuit 292 of FIG. 2, in accordance with various embodiments.

FIG. 7B depicts another example plot of delay versus time for the tunable delay circuit 292 of FIG. 2, in accordance with various embodiments.

FIG. 8 depicts a flowchart of an example process for operating the duty cycle evaluation circuit 200 of FIG. 2A, consistent with FIG. 7A, in accordance with various embodiments.

FIG. 9 depicts a flowchart of another example process for operating the duty cycle evaluation circuit 200 of FIG. 2A, consistent with FIG. 7B, in accordance with various embodiments.

FIG. 10 illustrates an example of components that may be present in a computing system 1050 for implementing the techniques (e.g., operations, processes, methods, and methodologies) described herein.

### DETAILED DESCRIPTION

As mentioned at the outset, various challenges are presented in ensuring that the duty cycle of a clock signal or other periodic signal is accurate.

A clock signal in a circuit has various purposes including synchronization of different parts of the circuit, sequential logic operations in digital circuits such as flip-flops and registers, timing control, e.g., how fast data can be processed and transmitted, power management, e.g., gating or disabling portions of the circuit when they are not actively needed, and communication between components, e.g., ensuring the components are in sync to facilitate the reliable exchange of data.

The duty cycle of a clock signal is the percentage of the waveform period that the waveform is at a logic high level. The duty cycle should closely match the designed level to ensure the accurate operation of a circuit. A duty cycle of 50% is commonly used to accommodate synchronous logic components that operate on rising and falling edges of a clock signal.

A duty cycle monitoring circuit, also referred to as a Duty Cycle Regulator (DCR), can be used to measure and adjust the duty cycle. For example, the DCR can be the measurement and decision-making portion of an all-digital clock duty cycle regulation loop used by clocking circuits, sometimes referred to as Intellectual Property (IP) blocks, and other customers such as a Double Data Rate (DDR) interface to main system memory. A DCR in the context of an all-digital clock duty cycle regulation loop is a component or mechanism used to monitor and regulate the duty cycle of a digital clock signal. The DCR serves as a feedback control mechanism that repeatedly monitors the duty cycle of the clock signal and adjusts it if it deviates from the desired value.

However, developing the mixed-signal measurement core, and closing timing on the sequential logic, have become more difficult as process generations advance.

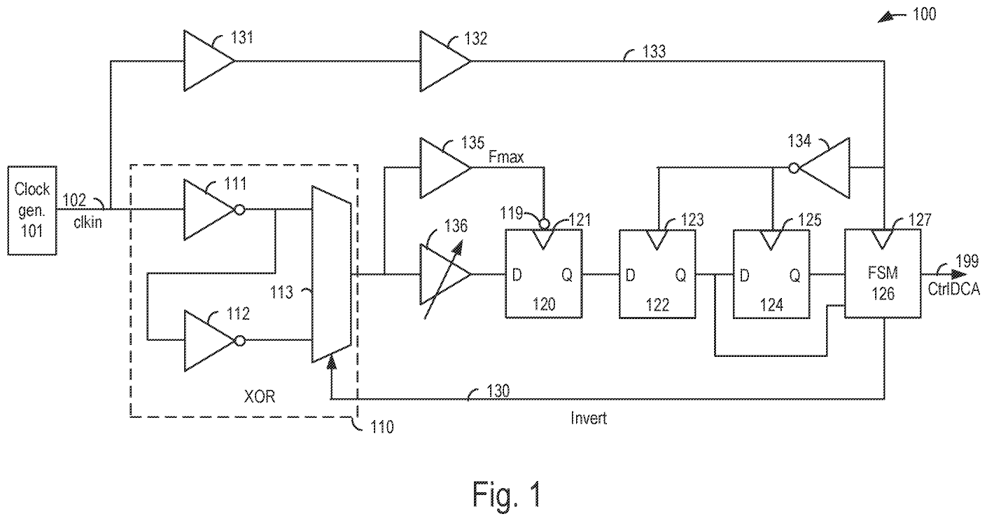

For example, buffering (such as depicted by the buffer 135 in FIG. 1) is required to keep the minimum-measurable pulse width small, as required by regulating high-frequency input clocks. This, in turn, requires large matching buffering (e.g., buffers 131 and 132).

Some solutions involve large-circumference digital timing paths. Achieving a narrow minimum-measurable clock phase requires the core to offset fixed data-tuner latency via clock-side buffers (e.g., buffer 135). Those have to in turn be matched on the finite state machine (FSM) clock path for proper timing; uncertainty increases with the total stage count of these two pathways. Assuming there is a buffer for minimum delay safety, a higher core frequency therefore causes lower FSM frequency. This is a difficult dilemma even if the extra area and power costs of all those buffers can be accepted.

Some solutions further involve transistor-level content. The core requires a sampling element, a delay tuner, and a low-distortion exclusive-or (XOR). A standard-cell flip-flop suffices for the first; for the second, a widely-reused custom tuner topology works well. The unique XOR is another matter: customizations to limit measurement self-error have resulted in a circuit unsuited to formal equivalence with a register transfer level (RTL) implementation.

Instead, a cost is paid in terms of transistor-level layout and full characterization-without the benefits of formal verification—with every new process node. The cost of this strategy is rising rapidly with the number of nodes needing simultaneous support.

Formal equivalence checking process is a part of electronic design automation, used during the development of digital integrated circuits, to formally prove that two representations of a circuit design exhibit exactly the same behavior. RTL abstraction is used in hardware description languages like Verilog and Very High Speed Integrated Circuit Hardware Description Language (VHDL) to create high-level representations of a circuit, from which lower-level representations and ultimately actual wiring can be derived.

The solutions provided herein address the above and other issues. In one aspect, the solutions include a duty cycle monitoring circuit with a topological change that fundamentally improves the timing situation, while converting most of the core into standard cell logic amenable to RTL realization. Measurement cadence is also maximized without compromising metastable resolution.

In an example implementation, a duty cycle evaluation circuit includes a finite state machine (FSM), a logic circuit coupled to the FSM, a tunable delay circuit having an input coupled to an output of the logic circuit, a flip-flop having clock input coupled to the input of the tunable delay circuit and a data input coupled to an output of the tunable delay circuit, a first sampling circuit having a data input coupled to a data output of the flip-flop, a data output coupled to the FSM and a clock input coupled to the FSM, and a second sampling circuit having a data input coupled to the data output of the flip-flop, a data output coupled to the FSM and a clock input coupled to the FSM.

The solutions include a number of advantages. For example, the solution can be implemented using standard cells to generate the core's measurement events as part of revised FSM logic. Except for the internal components of the delay tuner, the entire circuit can directly be represented in RTL and converged using digital timing tools, with an optimized inner control loop cadence.

Maintaining standard cell logic is easier both for design engineers and mask designers than the transistor-level XOR would be, and the result is now open to the full digital validation suite. Since the “core” now looks like regular FSM timing paths, clock buffering (and the timing circumference tax it imposes on maximum clock frequency (Fmax)) is drastically reduced. Despite shortening the inner control loop cadence to five clock cycles, for example, metastable resolution is actually improved due to better core retiming.

These and other features will be further apparent in view of the following discussion.

FIG. 1 depicts an example duty cycle evaluation circuit 100, in accordance with various embodiments. The circuit receives an input clock signal, clkin, on a path 102 from a clock generator 101 which can include, e.g., a delay-locked loop (DLL) or phase-locked loop (PLL) which regulates the frequency and duty cycle of the clock signal. The DLL or PLL may receive a periodic signal from a crystal resonator, for instance. The clock signal is provided to an XOR circuit 110 which includes inverters 111 and 112 and a multiplexer 113, which passes the output from one of the inverters based on a selection signal on an invert path 130. An FSM 126 provides an output on the invert path as well as a duty cycle adjustment control signal, CtrlDCA, which can be fed back to the clock generator.

The clock signal is also provided to a clock input 127 of the FSM via a path 133 and matching buffers 131 and 132. The path 133 is coupled to an inverter 134 having an output coupled to clock inputs 123 and 125 of flip-flops 122 and 124, respectively. An output of the multiplexer is provided to an input of a buffer 135 and a tunable buffer 136. The output of the buffer 135 is a signal having a frequency Fmax which is input to a clock input 121 of a flip-flop 120, via an inverter 119. The output of the tunable buffer 136 is provided to a data input (D) of the flip-flop 120. The flip-flops 120, 122 and 124 may be D-type flip-flops, for example, which each include a data input (D) and a data output (Q).

The output (Q) of the flip-flop 120 is provided to the input (D) of the flip-flop 122, and the output (Q) of the flip-flop 122 is provided to the input (D) of the flip-flop 124 and to the FSM. The output (Q) of the flip-flop 124 is also provided to the FSM.

The circuit 100 includes a transistor-level XOR 110, as well as long timing paths from the Point-Of-Divergence (POD) of clkin to the flip-flop 122 which is a first retiming flip-flop. In total, there are 8-9 complementary metal-oxide-semiconductor (CMOS) stages on each side of the path. Both values of “Invert” on path 130 are used sequentially in making a duty cycle measurement, meaning the timing path from the core flip-flop to the retiming flip-flop 122 is alternately full-cycle and half-cycle. This matters because the core data is intentionally tuned to near metastability; the more setup time for resampling by the retiming flip-flop 122, the better the metastable resolution. Note also that the retiming flip-flop 122 is overwritten twice during a full measurement, further taxing metastability. The core includes the buffer 135, tunable buffer 136, flip-flops 120, 122 and 124 and inverter 134.

The “inner control loop” of the circuit 100 measures a high phase, inverts the clock, measures the low phase, updates the tunable delay or duty cycle adjust value, and un-inverts the clock, all on a fixed sixteen input-clock cadence. This includes ample timing padding, whose removal would improve regulation settling time (and hence overall PLL lock time in certain DCR run modes).

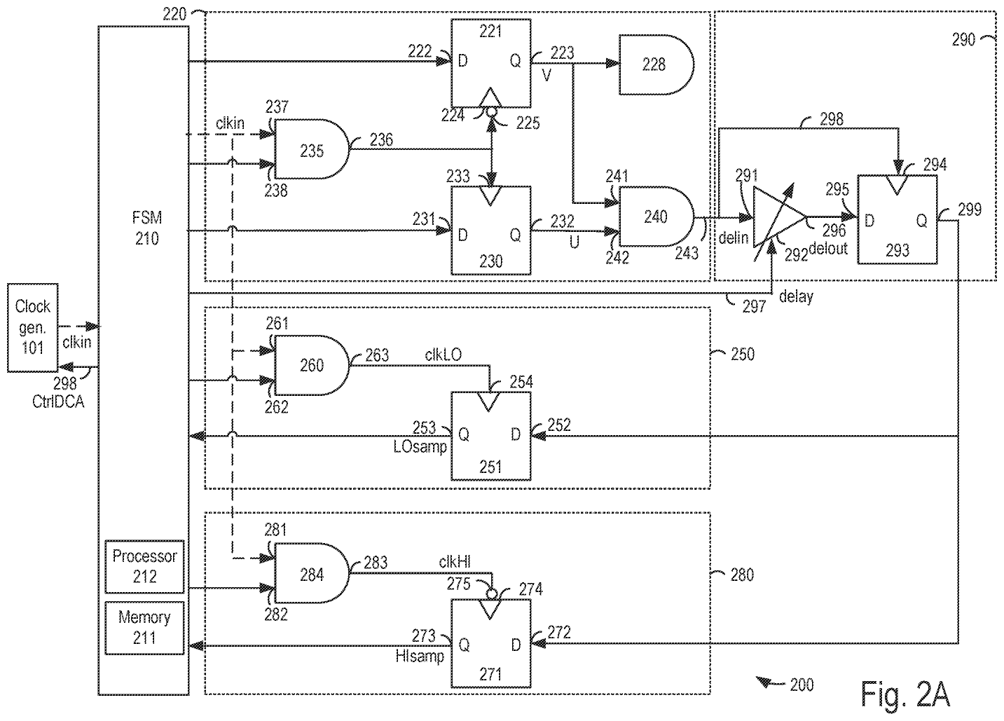

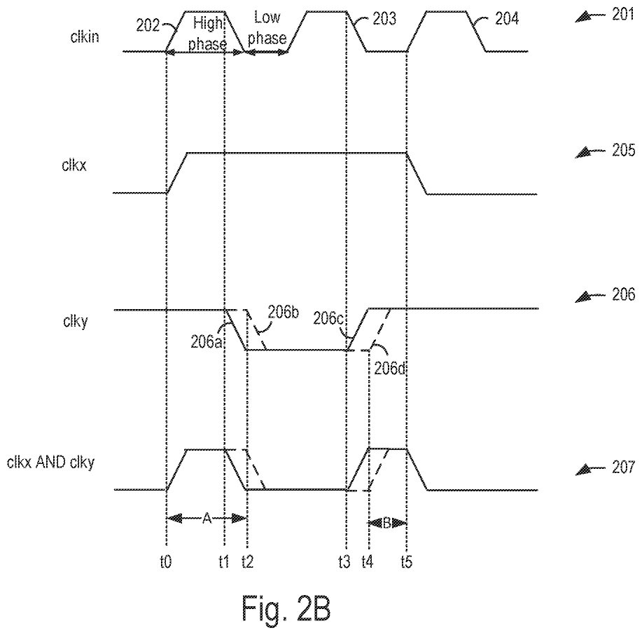

FIG. 2A depicts another example duty cycle evaluation circuit 200, in accordance with various embodiments. The circuit includes a FSM 210 which receives clkin from the clock generator. Note that while an FSM is depicted, any type of control circuit can be used. Dashed lines indicate a path of clkin. The FSM can be implemented with hardware and/or software. The FSM can include a memory 211 which stores instructions to be executed by a processor 212 or other control circuit to provide the functions described herein. The circuit 200 further includes a logic circuit 220, a first sampling circuit 280, a second sampling circuit 250, and a delay-and-latch circuit 290. The logic circuit 220 receives clkin and other control signals from the FSM and, in response, provides first and second pulses to the delay-and-latch circuit 290 at the input 291 (e.g., input node or path) of a tunable delay circuit 292 such as a tunable buffer. Delin is the value at the input 291 of the tunable delay circuit 292. A delay of the tunable delay circuit can be set by the FSM via a delay signal on a path 297. Delout, which is a delayed version of delin based on a delay imposed by the tunable delay circuit 292, is at the output 296.

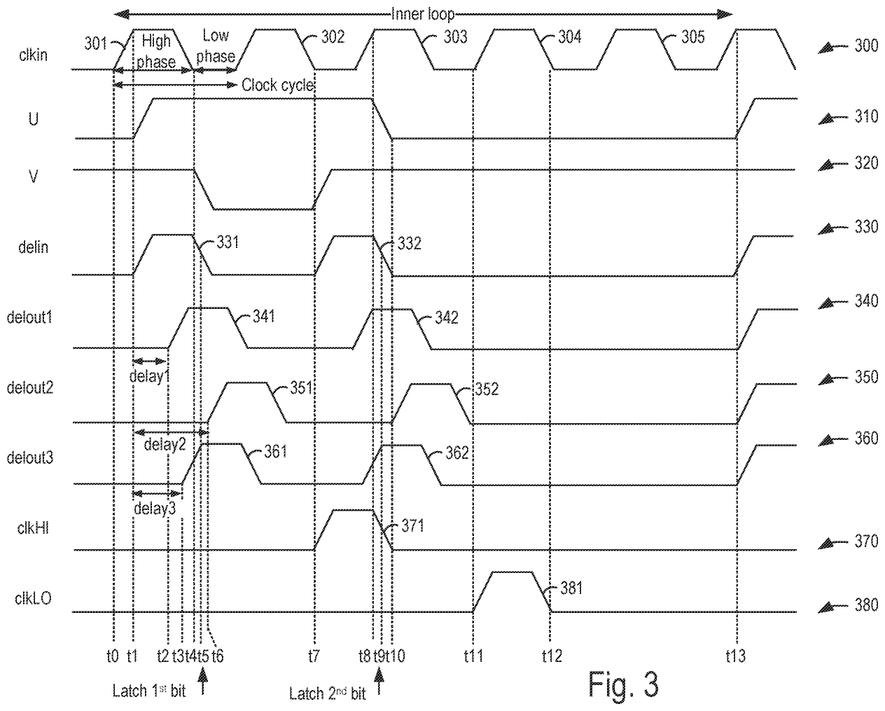

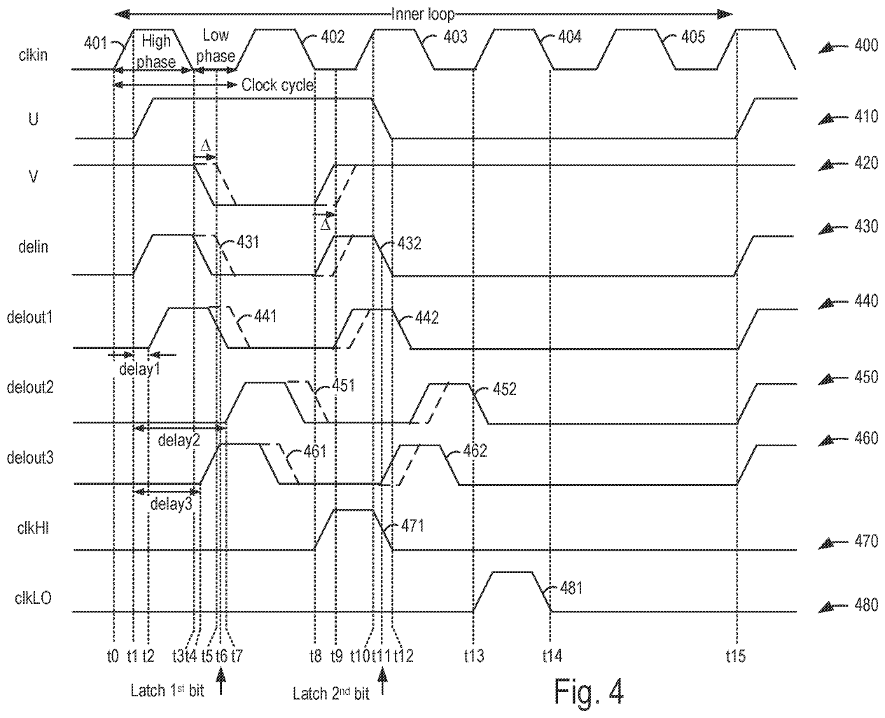

The delay-and-latch circuit 290 further includes a flip-flop (e.g., a flip-flop circuit) 293 which receives the first and second pulses at both a clock input 294, via a path 298, and a data input 295 (D). The flip-flop 293 includes a data output 299 coupled to data inputs 252 and 272 of the flip-flops 251 and 271, respectively. The data input 295 is coupled to the output 296 (e.g., output node or path) of the delay circuit so that the data input of the flip-flop 293 is delayed relative to the clock input of the flip-flop 293. The flip-flop may be a falling edge-triggered D-type flip flop, in one example implementation. The flip-flop latches a bit which is a function of a delay of the tunable delay circuit 292, as described further in connection with FIGS. 3 and 4.

The logic circuit 220 includes flip-flops 221 and 230, AND gates 235 and 240 and a sideload 228. An electrical sideload is a device placed in parallel with a load to delay a pair of electrical events (e.g., the trailing edge of the first measurement pulse, and the leading edge of the second measurement pulse) to compensate for intrinsic inequalities stemming from transistor behavior, etc. See also FIG. 2B. Sideloading widens the measurement “delin” HI pulse, narrowing the LO pulse in equal and opposite ways. The circuit 100 of FIG. 1 tries to minimize self-error (e.g., the delta between measured 50% and actual 50% duty cycle) by meticulously matching P/N strength for every stage inside the core XOR. In contrast, the circuit 200 of FIG. 2A uses a side load sideload on U or V, achieved via standard cells with unused inputs tied off to prevent the output from switching. Sideload strength adjustments involve a cell-size swap: far less likely to run afoul of base-layer design rule checks (DRCs) and/or active-vs-dummy device rules. DRC verifies as to whether a specific design meets the constraints imposed by the process technology to be used for its manufacturing. Studies estimate a 50% effort savings from the elimination of the device-level XOR.

Also in the logic circuit 220, the flip-flop 221 has a data input 222 which receives a control signal from the FSM, a data output 223 (denoted by V) coupled to the sideload 228 and to an input 241 of the AND gate 240, and a clock input 224 coupled via an inverter 225 to an output 236 of the AND gate 235. The flip-flop 230 has a data input 231 which receives a control signal from the FSM, a data output 232 (denoted by U) coupled to an input 242 of the AND gate 240, and a clock input 233 coupled (without inversion) to the output 236 of the AND gate 235. The AND gate 240 includes inputs 241 and 242 and an output 243 coupled to the input 291 of the tunable delay circuit 292. The AND gate 235 includes an input 237 which receives clkin and an input 238 which receives a control signal from the FSM.

The first sampling circuit 280 latches a first bit of data from the output 299 of the flip-flop 293, after which the second sampling circuit 250 latches a second bit of data from the output 299 of the flip-flop 293. After being latched, the first bit is provided from the output 273 of the flip-flop 271 to the FSM as HIsamp, and the second bit is provided from the output 253 of the flip-flop 251 to the FSM as LOsamp. The FSM forms a code comprising the first and second bits which indicates a timing of the high and low phases of clkin. Based on the code, the FSM can adjust the delay of the tunable delay circuit 292 in multiple iterations of a feedback loop, as discussed further below, until a balanced state is reached. After a number N of the iterations, the FSM can provide CtrlDCA at an output path 298 to the clock generator 101 for use therein in adjusting its duty cycle. This process can be performed repeatedly until the overall duty cycle regulation loop has converged.

The first sampling circuit 280 includes an AND gate 284 which receives clkin at one input 281 and a control signal from the FSM at another input 282. The AND gate 284 has an output 283 (clkHI) coupled to a clock input 274 of the flip-flop 271 via an inverter 275.

The second sampling circuit 250 includes an AND gate 260 which receives clkin at one input 261 and a control signal from the FSM at another input 262. The AND gate 260 has an output 263 (clkLO) coupled to a clock input 254 of the flip-flop 251. clkLO and clkHI are retimer clocks.

The output of an AND gate is high only when both inputs are high.

The flip-flops 251 and 271 can be positive or rising edge triggered, in one approach. The flip-flop 293 can be negative or falling edge triggered, in one approach.

Generally, clkin clocks all sequential elements of the FSM, as well as the core and resampler, in one or two CMOS stages past the POD. Over a half-cycle's worth of delay is removed versus the approach of FIG. 1, and with it the corresponding amount of uncertainty-based timing penalty. Nodes “U” and “V” are peers to the rest of the FSM state, and from them the input to the delay line and sampling clock is only one AND gate later in time. Given the way U and V are generated (see FIGS. 3 and 4), this means a full-cycle path from the “core” sampling element to both HI and LO retiming flip-flops, which are no longer clocked serially: both advantageous from a metastability standpoint.

The core clock path buffers have been removed thanks to internal improvements in the delay tuner, maximizing resolution time for the retimer inputs. Should the delay tuner's fixed latency still be too high, sampler clock buffers can be reintroduced without perturbing the rest of the FSM clocks, providing a knob to trade off resolution time between the input and output side of the retimers—all in full view of the static timing tools.

The core includes the logic circuit 220 and the delay-and-latch circuit 290.

FIG. 2B depicts example plots which explain the operation of the sideload 228 of FIG. 2A, in accordance with various embodiments. A plot 201 depicts clkin which has first, second and third pulses 202, 203 and 204, respectively. A plot 205 depicts clkx, a plot 206 depicts clky and a plot 207 depicts clkx AND clky. In a circuit pathway with a clear driver and receiver, a sideload is a supplementary receiver sharing a driver with the primary receiver(s) but not providing downstream functionality of its own: its purpose is to slow down the electrical transition experienced by the primary receiver(s). For the sideload 228, in this simplified example, clkX and clkY are outputs from the main FSM. The sideload on clkY will delay it according to how large the sizing-dependent sideload's input capacitance is, which alters the relative width of the “A” and “B” pulses (which are the AND of clkX and clkY). For example, a delay of t2−t1 or t4−t3 is represented by plots 206a and 206b, and plots 206c and 206d, respectively. Corresponding delays are depicted in the plot 207 by the dashed lines. If the clkin duty cycle is 50%, the quantity (A−B)/2 is the measurement self-error of the duty cycle evaluation circuit; the size of the sideload on clkY is chosen to make A and B as close as possible (assuming 50% duty cycle input) and therefor putting the self-error as close to zero as possible.

FIG. 3 depicts example plots of signals in the circuit 200 of FIG. 2A when a clock signal has a duty cycle of 50%, when the sideload 228 is not used, in accordance with various embodiments. The use of the sideload is optional.

The plots represent voltage versus time and extend over one inner control loop which comprises five consecutive clock cycles of clkin (plot 300), as represented by clock pulses 301-305, in this example. The inner control loop is also referred to as an inner control loop cadence. The plots 310 and 320 represent U and V, respectively, from FIG. 2A. Each clock cycle includes a high phase (when clkin is high) and a low phase (when clkin is low), where the duration of the high phase divided by the clock cycle represents the duty cycle.

Delin (plot 330) is the value at the input 291 to the tunable delay circuit 292. At the AND gate 240, delin is high only when U and V are high. Otherwise, delin is low.

Delout1, delout2 and delout3 (plots 340, 350 and 360, respectively) are example values at the output 296 of the tunable delay circuit 292, in a case where the delay of the tunable delay circuit 292 is too short, too long, or just right (at a balanced state).

clkHI and clkLO (plots 370 and 380, respectively) are the clock inputs to the flip-flops 271 and 251, respectively.

Clkin begins to transition high at t0. When clkin reaches the high level at t1, this causes U to increase from low to high, which in turn causes delin to increase from low to high in a first pulse 331. When clkin decreases back to low at t4, this causes V to decrease from high to low, which in turn causes delin to transition from high to low. When clkin at the pulse 302 reaches the low level at t7, this causes V to increase from low to high, which in turn causes delin to increase again from low to high, in a second pulse 332. When the third pulse 303 of clkin reaches the high level at t8, this causes U to decreases from high to low, which in turn causes delin to decrease from high to low.

Since delin is the clock signal of the flip-flop 293, the flip-flop will latch the delayed version of delin, delout, at a falling edge of delin, when the flip-flop 293 is falling edge triggered. The falling edges of the delin pulses 331 and 332 which indicate the time of the latching are depicted at t5 and t9, respectively. The flip-flop 293 will latch a high value, e.g., 1, if delout is high when falling edge of delin triggers latching in the flip-flop. The flip-flop 293 will latch a low value, e.g., 0, if delout is low when falling edge of delin triggers latching in the flip-flop. Accordingly, the delay of the tunable delay circuit 292 dictates whether a 0 or 1 is latched. If the delay is relatively small, a 1 is latched (see delout1). If the delay is relatively large, a 0 is latched (see delout2). If the delay is at a balanced level, as with delout3, the flip-flop 293 is at the cusp of latching a 0 or 1.

Delout1 includes pulses 341 and 342 which are delayed relative to pulses 331 and 332, respectively, by a first delay, delay1=t2−t1. When the flip-flop 293 latches at t5 and t9, the pulses 341 and 342, respectively, are clearly high, so that a logical high level (1) is latched.

Delout2 includes pulses 351 and 352 which are delayed relative to pulses 331 and 332, respectively, by a second delay, delay2=t6−t1. When the flip-flop 293 latches at t5 and t9, the pulses 351 and 352, respectively, are clearly low, so that a logical low level (0) is latched.

Delout3 includes pulses 361 and 362 which are delayed relative to pulses 331 and 332, respectively, by a third delay, delay3=t3−t1. When the flip-flop 293 latches at t5 and t9, the pulses 351 and 352, respectively, are at the cusp of the high level, so that a 1 is latched. This delay is considered to represent an example of a balanced state since the delay is at the cusp of latching a 0 or 1.

clkHI includes a pulse 371 which increases from low to high at t7 in response to clkin at the pulse 302 reaching the low level. This pulse causes latching of a first bit from the flip-flop 293 at the flip-flop 271.

clkLO includes a pulse 381 which increases from low to high at t11 in response to clkin at the pulse 304 transitioning from low to high. This pulse causes latching of a first bit from the flip-flop 293 at the flip-flop 251.

In the time period t12-t13, the FSM processes the first and second bits as a code word, decides whether to adjust a delay of the tunable delay circuit 292, and performs an adjustment of the tunable delay circuit 292 if warranted. The adjustment can be performed in each inner control loop of a plurality of consecutive inner control loops. After a number N of inner control loops (e.g., after one outer control loop), the FSM can output CtrlDCA to the clock generator to inform the clock generator that the duty cycle should be increased or decreased. In one approach, the clock generator filters the information from the FSM to avoid a high frequency of adjustments. In another approach, the FSM performs the filtering and provide a filtered instruction to the clock generator.

In one approach, CtrlDCA is a “sign bit” indicating the polarity of the adjustment to be made at the clock generator (increase or decrease). For example, if the FSM increases the delay after a number N of inner control loops, the duty cycle of the clock generator is too high and should be reduced. If the FSM decreases the delay after a number N of inner control loops, the duty cycle of the clock generator is too low and should be increased. This approach is referred to as “bang-bang” control system. Various duty cycle regulation techniques can be used in a PLL of a clock generator, for instance, to converge the duty cycle of clkin based on the successive values of CtrlDCA. In one approach, the FSM tracks whether the delay has increased or decreased over the current N inner control loops.

FIG. 3 also shows how the inner control loop length is minimized. The high phase measurement requires one input clock phase, followed by a two-phase pause for some metastable resolution before retiming by clkHI. The same is then repeated for the low phase, culminating in a clkLO edge that comes three input periods after the sequence began. One full cycle is then allotted to calculate the DCR's next move, with aggressive pre-calculation to minimize the logic path from “LO” to a decision; and one final cycle is allotted to making that move (updating the tunable delay or the duty cycle adjustor): a total of 5 input clocks, with nothing further to trim that wouldn't seriously compromise timing closure.

The delin pulse 331 is an example of a first pulse which has a transition of a first polarity (e.g., positive at t1) which is based on a same-polarity transition of the clock signal (e.g., first clock pulse 301 which has a positive transition at t0), and delin pulse 332 is an example of a second pulse which has a transition of the first polarity (e.g., positive at t7) which is based on an opposite-polarity transition of the clock signal (e.g., second clock pulse 302 which has a negative transition at t7).

FIG. 4 depicts example plots of signals in the circuit 200 of FIG. 2A when a clock signal has a duty cycle of 50%, when the sideload 228 is used, in accordance with various embodiments. The sideload provides a trim mechanism which can be across different processes voltages and temperatures (PVT): with a well-chosen fixed sideload, the circuit can meet a ±1% self-error target across the entire simulation envelope.

As mentioned, sideloading of the V value in FIG. 2A widens the measurement “delin” HI pulse 331, narrowing the LO pulse 332 in equal and opposite ways. Alternatively, a sideload can be coupled to the U value to narrow the measurement “delin” HI pulse and widen the LO pulse in equal and opposite ways.

In this example, the change in the timing of the signals relative to FIG. 3 is indicated by dashed lines.

The plots represent voltage versus time and extend over one inner control loop which comprises five clock cycles of clkin (plot 400), as represented by clock pulses 401-405. The plots 410 and 420 represent U and V, respectively, from FIG. 2A. Each clock cycle includes a high phase (when clkin is high) and a low phase (when clkin is low), where the duration of the high phase divided by the clock cycle represents the duty cycle.

Delout1, delout2 and delout3 are example values at the output 296 of the tunable delay circuit 292, in a case where the delay of the tunable delay circuit 292 is too short, too long, or just right (at a balanced state).

Clkin begins to transition high at t0. When clkin reaches the high level at t1, this causes U to increase from low to high, which in turn causes delin (plot 430) to increase from low to high in a first pulse 431. U is not delayed since it does not have the sideload. When clkin decreases back to low at t4, this causes V to decrease from high to low. However, this decreases is delayed from t4 to t5 (Δ) due to the sideload 228. The decrease of V at t5 causes delin to transition from high to low at t5. When clkin at the pulse 402 reaches the low level at t8, this causes V to increase from low to high at t9 instead of t8 due to the delay Δ. The increase in V causes delin to increase again from low to high, in a second pulse 432. When the third pulse 403 of clkin reaches the high level at t10, this causes U to decreases from high to low, which in turn causes delin to decrease from high to low. The widths of the first and second pulses of delin are thus increase and decreased, respectively.

Due to the different pulse widths, the balanced state for delin is at the trailing edge of the first pulse and the leading edge of the second pulse. In contrast, in FIG. 3, the balanced state for delin is at the trailing edge for both the first and second pulses.

As mentioned, the flip-flop 293 will latch the delayed version of delin, delout, at a falling edge of delin. The falling edges of the delin pulses 431 and 432 which indicate the time of the latching are depicted at t6 and t11, respectively.

Delout1 (plot 440) includes pulses 441 and 442 which are delayed relative to pulses 431 and 432, respectively, by a first delay, delay1=t2−t1. When the flip-flop 293 latches at t6 and t11, the pulses 441 and 442, respectively, are clearly high, so that a logical high level (1) is latched.

Delout2 (plot 450) includes pulses 451 and 452 which are delayed relative to pulses 431 and 432, respectively, by a second delay, delay2=t7−t1. When the flip-flop 293 latches at t6 and t11, the pulses 451 and 452, respectively, are clearly low, so that a logical low level (0) is latched.

Delout3 (plot 460) includes pulses 461 and 462 which are delayed relative to pulses 431 and 432, respectively, by a third delay, delay3=t4−t1. When the flip-flop 293 latches at t6 and t11, the pulses 451 and 452, respectively, are at the cusp of the high level, so that a 1 is latched. This delay is considered to represent an example of a balanced state since the delay is at the cusp of latching a 0 or 1.

clkHI (plot 470) includes a pulse 471 which increases from low to high at t8 in response to clkin at the pulse 402 reaching the low level. This pulse causes latching of a first bit from the flip-flop 293 at the flip-flop 271.

clkLO (plot 480) includes a pulse 481 which increases from low to high at t13 in response to clkin at the pulse 404 transitioning from low to high. This pulse causes latching of a first bit from the flip-flop 293 at the flip-flop 251.

In the time period t14-t15, the FSM processes the first and second bits as a code word, decides whether to adjust a delay of the tunable delay circuit 292, and performs an adjustment of the tunable delay circuit 292 if warranted.

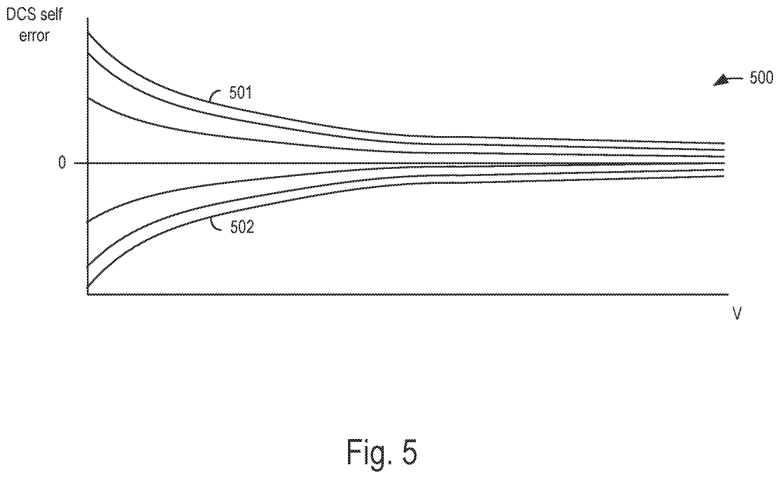

FIG. 5 depicts an example set of plots 500 indicating a duty cycle self-error versus voltage, in accordance with various embodiments. The plots include an upper boundary plot 501 and a lower boundary plot 502. The plots demonstrate that the duty cycle self-error is well-controlled, e.g., in the range of single digit picoseconds, across a wide range of input voltages and at a worst case temperature.

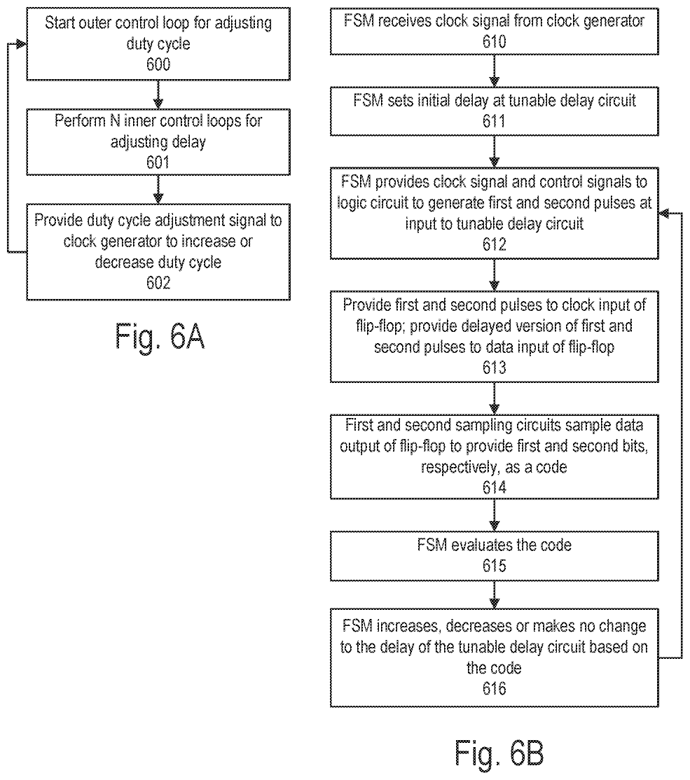

FIG. 6A depicts a flowchart of an example process for operating a duty cycle evaluation circuit, consistent with the circuit 200 of FIG. 2A, in accordance with various embodiments. Block 600 starts an outer control loop for adjusting the duty cycle. Block 601 includes performing a number N>1 inner control loops for adjusting the delay. Block 602 includes providing a duty cycle adjustment signal to a clock generator to increase or decrease its duty cycle.

FIG. 6B depicts a flowchart of an example implementation of the inner control loop of FIG. 6A, in accordance with various embodiments. The flowcharts provide a general description. The operations are not necessarily performed as discrete operations at different times but can occur concurrently, at least in part. At block 610, the FSM receives a clock signal from a clock generator. At block 611, the FSM sets an initial delay at the tunable delay circuit. At block 612, the FSM provides the clock signal and control signals to a logic circuit to generate first and second pulses at the input to the tunable delay circuit. Block 613 includes providing first and second pulses to the clock input of the flip-flop 293, and providing a delayed version of the first and second pulses to a data input of the flip-flop. At block 614, the first and second sampling circuits sample data which is output from the flip-flop to provide first and second bits, respectively, as a code.

At block 615, the FSM evaluates the code. For example, if both bits are high (11), this indicates the delay is to short and should be increased. If both bits are low (00), this indicates the delay is too long and should be decreased. If one bit is high and the other is low, this indicates the delay is at or close to a balanced value so no change in the delay is indicated. At block 616, the FSM increases, decreases or makes no change to the delay of the tunable delay circuit based on the code.

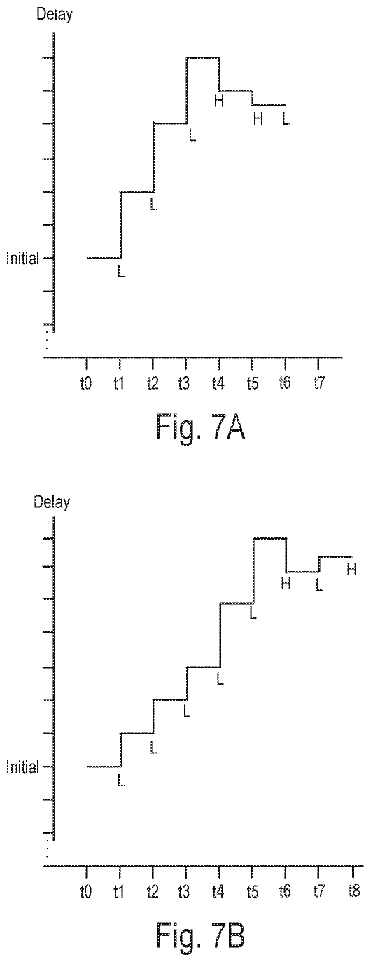

FIG. 7A depicts an example plot of delay versus time for the tunable delay circuit 292 of FIG. 2, in accordance with various embodiments. As mentioned, in each inner control loop, the FSM can evaluate a code which indicates whether the delay of the tunable delay circuit is too short (high or H bits—11) or too long (low or L bits—00) and make adjustments accordingly. The adjustment size can vary in this process. For example, an initial adjustment size may be two steps or increments as shown at t1, t2 and t3 when the L bits are received. At t4, the H bits are received, so that the polarity of the adjustment is switched, e.g., from positive (increase) to negative (decrease). In this example, the adjustment size is also reduced by one half, to one increment instead of two increments, since the delay is starting to converge to a final value. At t5, the H bits are received again, and the adjustment size is reduced by one half again, to one half increment. At t6, the L bits are received, representing a second polarity change. The second polarity change represents a balanced state in this example so that no further adjustment of the delay is made in this inner control loop. Due to noise and other factors, additional adjustments to the delay may occur in subsequent inner control loops.

In this example, an initial adjustment size is used until there is a polarity change, then each successive adjustment size is reduced. Also, a second polarity change represents a balanced state. Generally, the occurrence of a specified number of polarity changes in an inner control loop may represent a balanced state.

FIG. 7B depicts another example plot of delay versus time for the tunable delay circuit 292 of FIG. 2, in accordance with various embodiments. Here, the initial adjustment size is set at one increment until a threshold number of adjustments, e.g., three, of the same polarity have been made, at t1, 2 and t3. At t4, the adjustment is then increases, e.g., to two increments. The two increment adjustment can then continue for a threshold number of times until there is a polarity reversal. In this example, the two increment adjustment is repeated at t5 since L bits are received. However, at t6, H bits are received so that there is a polarity reversal in the adjustment. The adjustment is now negative at t6 and also reduced in size by one half, to one increment. At t7, there is a second polarity reversal as L bits are received. The adjustment is now positive at t7 and also reduced in size by one half again, to one quarter increment. At t8, there is a third polarity reversal as H bits are received. Assuming a threshold of three polarity reversals, the processes reaches a balanced state.

Various other approaches can be used which involve a variable gain to adjust the delay of the tunable delay circuit 292. The gain is the adjustment size of the delay in one inner control loop, for instance.

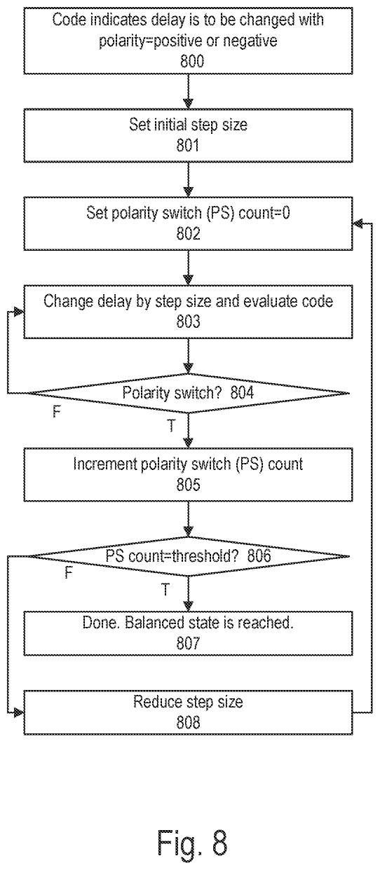

FIG. 8 depicts a flowchart of an example process for operating the duty cycle evaluation circuit 200 of FIG. 2A, consistent with FIG. 7A, in accordance with various embodiments. The process can be performed at the FSM, for example, in consecutive inner cycles. At block 800, the code indicates the delay is to be adjusted with a polarity=positive or negative. Block 801 sets an initial step size. Block 802 sets a polarity switch (PS) count=0. Block 803 changes the delay in the direction of the polarity by the step size and evaluates the resulting code. A decision block 804 determines whether the polarity has switched, e.g., from positive to negative or negative to positive. If the decision block 804 is false, block 803 is repeated. If the decision block 804 is true, block 805 increments the polarity switch (PS) count.

A decision block 806 determines whether the PS count has reached a threshold. If the decision block 806 is false, block 808 reduces the step size and block 802 follows. If the decision block 806 is true, block 807 indicates the process is done and a balanced state is reached.

Accordingly, a balanced state is reached when there is a threshold number of polarity switches in the adjustment, and the step size is decreased with each polarity switch.

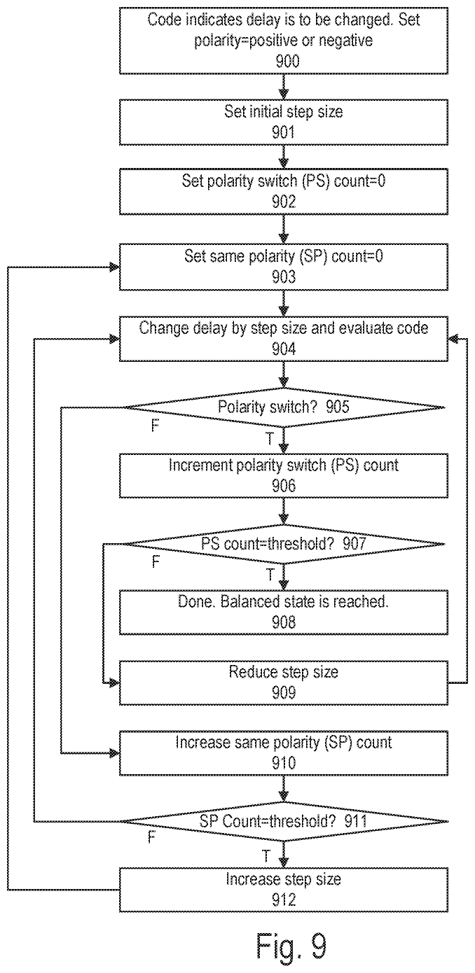

FIG. 9 depicts a flowchart of another example process for operating the duty cycle evaluation circuit 200 of FIG. 2A, consistent with FIG. 7B, in accordance with various embodiments. At block 900, the code indicates the delay is to be adjusted with a polarity=positive or negative. Block 901 sets an initial step size. Block 902 sets a polarity switch (PS) count=0. Block 903 sets a same polarity (SP) count=0. Block 904 changes the delay by the step size in the direction of the polarity and evaluates the resulting code. A decision block 905 determines whether the polarity has switched. If the decision block 905 is false, block 910 is reached, where the same polarity (SP) counted is increased. A decision block 911 then determines whether SP count=threshold. If the decision block 911 is false, block 904 is reached. If the decision block 911 is true, block 912 increase the step size of the adjustment and block 903 is then reached.

If the decision block 905 is true, block 906 increments the polarity switch (PS) count and a decision block 907 is reached. If the decision block 907 is true, the process is done and a balanced state is reached at block 908. If the decision block 907 is false, block 909 reduces the step size and block 904 follows.

Accordingly, a balanced state is reached when there is a threshold number of polarity switches in the adjustment, and the step size is increased when there is a threshold number of adjustments with the same polarity.

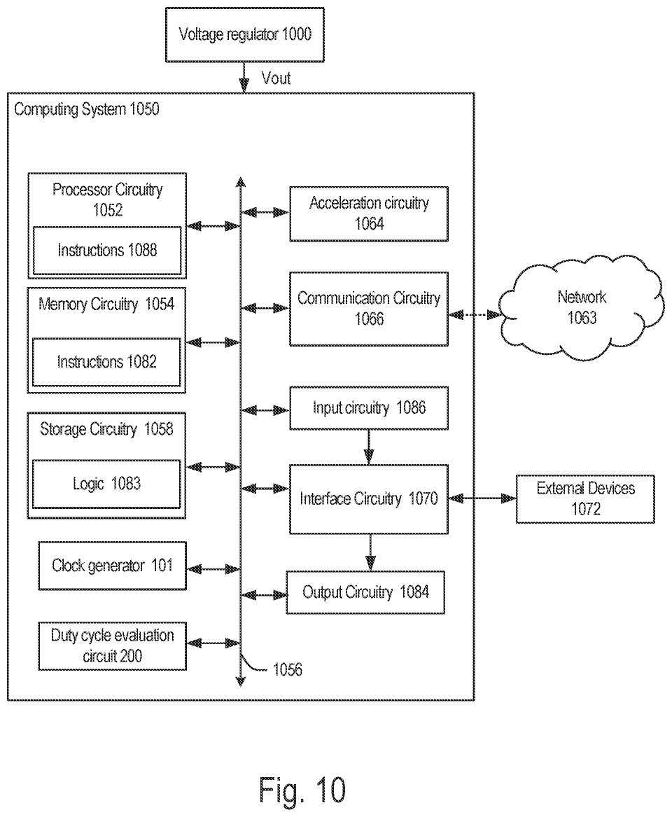

FIG. 10 illustrates an example of components that may be present in a computing system 1050 for implementing the techniques (e.g., operations, processes, methods, and methodologies) described herein. The clock generator 101 and the duty cycle evaluation circuit 200 are included in the computing system 1050 and may communicate with each other as well as other components via a bus 1056.

The computing system 1050 may include any combinations of the hardware or logical components referenced herein. The components may be implemented as ICs, portions thereof, discrete electronic devices, or other modules, instruction sets, programmable logic or algorithms, hardware, hardware accelerators, software, firmware, or a combination thereof adapted in the computing system 1050, or as components otherwise incorporated within a chassis of a larger system. For one embodiment, at least one processor 1052 may be packaged together with computational logic 1282 and configured to practice aspects of various example embodiments described herein to form a System in Package (SiP), or a System on Chip (SoC).

A voltage regulator 1000 may provide a voltage Vout to one or more of the components of the computing system 1250. The memory circuitry 1254 may store instructions and the processor circuitry 1252 may execute the instructions to perform the functions described herein.

The system 1050 includes processor circuitry in the form of one or more processors 1052. The processor circuitry 1052 includes circuitry such as, but not limited to one or more processor cores and one or more of cache memory, low drop-out voltage regulators (LDOs), interrupt controllers, serial interfaces such as SPI, I2C or universal programmable serial interface circuit, real time clock (RTC), timer-counters including interval and watchdog timers, general purpose I/O, memory card controllers such as secure digital/multi-media card (SD/MMC) or similar, interfaces, mobile industry processor interface (MIPI) interfaces and Joint Test Access Group (JTAG) test access ports. In some implementations, the processor circuitry 1052 may include one or more hardware accelerators (e.g., same or similar to acceleration circuitry 1064), which may be microprocessors, programmable processing devices (e.g., FPGA, ASIC, etc.), or the like. The one or more accelerators may include, for example, computer vision and/or deep learning accelerators. In some implementations, the processor circuitry 1052 may include on-chip memory circuitry, which may include any suitable volatile and/or non-volatile memory, such as DRAM, SRAM, EPROM, EEPROM, Flash memory, solid-state memory, and/or any other type of memory device technology, such as those discussed herein

The processor circuitry 1052 may include, for example, one or more processor cores (CPUs), application processors, GPUs, RISC processors, Acorn RISC Machine (ARM) processors, CISC processors, one or more DSPs, one or more FPGAs, one or more PLDs, one or more ASICs, one or more baseband processors, one or more radio-frequency integrated circuits (RFIC), one or more microprocessors or controllers, a multi-core processor, a multithreaded processor, an ultra-low-voltage processor, an embedded processor, or any other known processing elements, or any suitable combination thereof. The processors (or cores) 1052 may be coupled with or may include memory/storage and may be configured to execute instructions stored in the memory/storage to enable various applications or operating systems to run on the platform 1050. The processors (or cores) 1752 is configured to operate application software to provide a specific service to a user of the platform 1750. In some embodiments, the processor(s) 1752 may be a special-purpose processor(s)/controller(s) configured (or configurable) to operate according to the various embodiments herein.

As examples, the processor(s) 1052 may include an Intel® Architecture Core™ based processor such as an i3, an i5, an i7, an i9 based processor; an Intel® microcontroller-based processor such as a Quark™, an Atom™, or other MCU-based processor; Pentium® processor(s), Xeon® processor(s), or another such processor available from Intel® Corporation, Santa Clara, California. However, any number other processors may be used, such as one or more of Advanced Micro Devices (AMD) Zen® Architecture such as Ryzen® or EPYC® processor(s), Accelerated Processing Units (APUs), MxGPUs, Epyc® processor(s), or the like; A5-A12 and/or S1-S4 processor(s) from Apple® Inc., Snapdragon™ or Centriq™ processor(s) from Qualcomm® Technologies, Inc., Texas Instruments, Inc.® Open Multimedia Applications Platform (OMAP)™ processor(s); a MIPS-based design from MIPS Technologies, Inc. such as MIPS Warrior M-class, Warrior I-class, and Warrior P-class processors; an ARM-based design licensed from ARM Holdings, Ltd., such as the ARM Cortex-A, Cortex-R, and Cortex-M family of processors; the ThunderX2® provided by Cavium™, Inc.; or the like. In some implementations, the processor(s) 1052 may be a part of a system on a chip (SoC), System-in-Package (SiP), a multi-chip package (MCP), and/or the like, in which the processor(s) 1052 and other components are formed into a single integrated circuit, or a single package, such as the SoC boards from Intel® Corporation. Other examples of the processor(s) 1052 are mentioned elsewhere in the present disclosure.

The system 1050 may include or be coupled to acceleration circuitry 1064, which may be embodied by one or more AI/ML accelerators, a neural compute stick, neuromorphic hardware, an FPGA, an arrangement of GPUs, one or more SoCs (including programmable SoCs), one or more CPUs, one or more digital signal processors, dedicated ASICs (including programmable ASICs), PLDs such as complex (CPLDs) or high complexity PLDs (HCPLDs), and/or other forms of specialized processors or circuitry designed to accomplish one or more specialized tasks. These tasks may include AI/ML processing (e.g., including training, inferencing, and classification operations), visual data processing, network data processing, object detection, rule analysis, or the like. In FPGA-based implementations, the acceleration circuitry 1064 may comprise logic blocks or logic fabric and other interconnected resources that may be programmed (configured) to perform various functions, such as the procedures, methods, functions, etc. of the various embodiments discussed herein. In such implementations, the acceleration circuitry 1064 may also include memory cells (e.g., EPROM, EEPROM, flash memory, static memory (e.g., SRAM, anti-fuses, etc.) used to store logic blocks, logic fabric, data, etc. in LUTs and the like.

In some implementations, the processor circuitry 1052 and/or acceleration circuitry 1064 may include hardware elements specifically tailored for machine learning and/or artificial intelligence (AI) functionality. In these implementations, the processor circuitry 1052 and/or acceleration circuitry 1764 may be, or may include, an AI engine chip that can run many different kinds of AI instruction sets once loaded with the appropriate weightings and training code. Additionally or alternatively, the processor circuitry 1052 and/or acceleration circuitry 1064 may be, or may include, AI accelerator(s), which may be one or more of the aforementioned hardware accelerators designed for hardware acceleration of AI applications. As examples, these processor(s) or accelerators may be a cluster of artificial intelligence (AI) GPUs, tensor processing units (TPUs) developed by Google® Inc., Real AI Processors (RAPS™) provided by AlphaICs®, Nervana™ Neural Network Processors (NNPs) provided by Intel® Corp., Intel® Movidius™ Myriad™ X Vision Processing Unit (VPU), NVIDIA® PX™ based GPUs, the NM500 chip provided by General Vision®, Hardware 3 provided by Tesla®, Inc., an Epiphany™ based processor provided by Adapteva®, or the like. In some embodiments, the processor circuitry 1052 and/or acceleration circuitry 1764 and/or hardware accelerator circuitry may be implemented as AI accelerating co-processor(s), such as the Hexagon 685 DSP provided by Qualcomm®, the PowerVR 2NX Neural Net Accelerator (NNA) provided by Imagination Technologies Limited®, the Neural Engine core within the Apple® A11 or A12 Bionic SoC, the Neural Processing Unit (NPU) within the HiSilicon Kirin provided by Huawei®, and/or the like. In some hardware-based implementations, individual subsystems of system 1050 may be operated by the respective AI accelerating co-processor(s), AI GPUs, TPUs, or hardware accelerators (e.g., FPGAs, ASICs, DSPs, SoCs, etc.), etc., that are configured with appropriate logic blocks, bit stream(s), etc. to perform their respective functions.

The system 1050 also includes system memory 1054. Any number of memory devices may be used to provide for a given amount of system memory. As examples, the memory 1054 may be, or include, volatile memory such as random access memory (RAM), static RAM (SRAM), dynamic RAM (DRAM), synchronous DRAM (SDRAM), RAMBUS® Dynamic Random Access Memory (RDRAM®), and/or any other desired type of volatile memory device. Additionally or alternatively, the memory 1054 may be, or include, non-volatile memory such as read-only memory (ROM), erasable programmable ROM (EPROM), electrically erasable programmable (EEPROM), flash memory, non-volatile RAM, ferroelectric RAM, phase-change memory (PCM), flash memory, and/or any other desired type of non-volatile memory device. Access to the memory 1054 is controlled by a memory controller. The individual memory devices may be of any number of different package types such as single die package (SDP), dual die package (DDP) or quad die package (Q17P). Any number of other memory implementations may be used, such as dual inline memory modules (DIMMs) of different varieties including but not limited to microDIMMs or MiniDIMMs.

Storage circuitry 1058 provides persistent storage of information such as data, applications, operating systems and so forth. In an example, the storage 1058 may be implemented via a solid-state disk drive (SSDD) and/or high-speed electrically erasable memory (commonly referred to as “flash memory”). Other devices that may be used for the storage 1058 include flash memory cards, such as SD cards, microSD cards, XD picture cards, and the like, and USB flash drives. In an example, the memory device may be or may include memory devices that use chalcogenide glass, multi-threshold level NAND flash memory, NOR flash memory, single or multi-level Phase Change Memory (PCM), a resistive memory, nanowire memory, ferroelectric transistor random access memory (FeTRAM), anti-ferroelectric memory, magnetoresistive random access memory (MRAM) memory that incorporates memristor technology, phase change RAM (PRAM), resistive memory including the metal oxide base, the oxygen vacancy base and the conductive bridge Random Access Memory (CB-RAM), or spin transfer torque (STT)-MRAM, a spintronic magnetic junction memory based device, a magnetic tunneling junction (MTJ) based device, a Domain Wall (DW) and Spin Orbit Transfer (SOT) based device, a thyristor based memory device, a hard disk drive (HDD), micro HDD, of a combination thereof, and/or any other memory. The memory circuitry 1054 and/or storage circuitry 1058 may also incorporate three-dimensional (3D) cross-point (XPOINT) memories from Intel® and Micron®.

The memory circuitry 1054 and/or storage circuitry 1058 is/are configured to store computational logic 1083 in the form of software, firmware, microcode, or hardware-level instructions to implement the techniques described herein. The computational logic 1083 may be employed to store working copies and/or permanent copies of programming instructions, or data to create the programming instructions, for the operation of various components of system 1050 (e.g., drivers, libraries, application programming interfaces (APIs), etc.), an operating system of system 1050, one or more applications, and/or for carrying out the embodiments discussed herein. The computational logic 1083 may be stored or loaded into memory circuitry 1054 as instructions 1082, or data to create the instructions 1082, which are then accessed for execution by the processor circuitry 1052 to carry out the functions described herein. The processor circuitry 1052 and/or the acceleration circuitry 1064 accesses the memory circuitry 1054 and/or the storage circuitry 1058 over the interconnect (IX) 1056. The instructions 1082 direct the processor circuitry 1052 to perform a specific sequence or flow of actions, for example, as described with respect to flowchart(s) and block diagram(s) of operations and functionality depicted previously. The various elements may be implemented by assembler instructions supported by processor circuitry 1052 or high-level languages that may be compiled into instructions 1088, or data to create the instructions 1088, to be executed by the processor circuitry 1052. The permanent copy of the programming instructions may be placed into persistent storage devices of storage circuitry 1058 in the factory or in the field through, for example, a distribution medium (not shown), through a communication interface (e.g., from a distribution server (not shown)), over-the-air (OTA), or any combination thereof.

The IX 1056 couples the processor 1052 to communication circuitry 1066 for communications with other devices, such as a remote server (not shown) and the like. The communication circuitry 1066 is a hardware element, or collection of hardware elements, used to communicate over one or more networks 1063 and/or with other devices. In one example, communication circuitry 1066 is, or includes, transceiver circuitry configured to enable wireless communications using any number of frequencies and protocols such as, for example, the Institute of Electrical and Electronics Engineers (IEEE) 802.11 (and/or variants thereof), IEEE 802.23.4, Bluetooth® and/or Bluetooth® low energy (BLE), ZigBee®, LoRaWAN™ (Long Range Wide Area Network), a cellular protocol such as 3GPP LTE and/or Fifth Generation (5G)/New Radio (NR), and/or the like. Additionally or alternatively, communication circuitry 1066 is, or includes, one or more network interface controllers (NICs) to enable wired communication using, for example, an Ethernet connection, Controller Area Network (CAN), Local Interconnect Network (LIN), DeviceNet, ControlNet, Data Highway+, or PROFINET, among many others.

The IX 1056 also couples the processor 1052 to interface circuitry 1070 that is used to connect system 1050 with one or more external devices 1072. The external devices 1072 may include, for example, sensors, actuators, positioning circuitry (e.g., global navigation satellite system (GNSS)/Global Positioning System (GPS) circuitry), client devices, servers, network appliances (e.g., switches, hubs, routers, etc.), integrated photonics devices (e.g., optical neural network (ONN) integrated circuit (IC) and/or the like), and/or other like devices.

In some optional examples, various input/output (I/O) devices may be present within or connected to, the system 1050, which are referred to as input circuitry 1086 and output circuitry 1084. The input circuitry 1086 and output circuitry 1084 include one or more user interfaces designed to enable user interaction with the platform 1050 and/or peripheral component interfaces designed to enable peripheral component interaction with the platform 1050. Input circuitry 1086 may include any physical or virtual means for accepting an input including, inter alia, one or more physical or virtual buttons (e.g., a reset button), a physical keyboard, keypad, mouse, touchpad, touchscreen, microphones, scanner, headset, and/or the like. The output circuitry 1084 may be included to show information or otherwise convey information, such as sensor readings, actuator position(s), or other like information. Data and/or graphics may be displayed on one or more user interface components of the output circuitry 1084. Output circuitry 1084 may include any number and/or combinations of audio or visual display, including, inter alia, one or more simple visual outputs/indicators (e.g., binary status indicators (e.g., light emitting diodes (LEDs)) and multi-character visual outputs, or more complex outputs such as display devices or touchscreens (e.g., Liquid Crystal Displays (LCD), LED displays, quantum dot displays, projectors, etc.), with the output of characters, graphics, multimedia objects, and the like being generated or produced from the operation of the platform 1050. The output circuitry 1084 may also include speakers and/or other audio emitting devices, printer(s), and/or the like. Additionally or alternatively, sensor(s) may be used as the input circuitry 1084 (e.g., an image capture device, motion capture device, or the like) and one or more actuators may be used as the output device circuitry 1084 (e.g., an actuator to provide haptic feedback or the like). Peripheral component interfaces may include, but are not limited to, a non-volatile memory port, a USB port, an audio jack, a power supply interface, etc. In some embodiments, a display or console hardware, in the context of the present system, may be used to provide output and receive input of an edge computing system; to manage components or services of an edge computing system; identify a state of an edge computing component or service; or to conduct any other number of management or administration functions or service use cases.

The components of the system 1050 may communicate over the IX 1056. The IX 1056 may include any number of technologies, including ISA, extended ISA, I2C, SPI, point-to-point interfaces, power management bus (PMBus), PCI, PCIe, PCIx, Intel® UPI, Intel® Accelerator Link, Intel® CXL, CAPI, OpenCAPI, Intel® QPI, UPI, Intel® OPA IX, RapidIO™ system IXs, CCIX, Gen-Z Consortium IXs, a HyperTransport interconnect, NVLink provided by NVIDIA®, a Time-Trigger Protocol (TTP) system, a FlexRay system, PROFIBUS, and/or any number of other IX technologies. The IX 1056 may be a proprietary bus, for example, used in a SoC based system.

The number, capability, and/or capacity of the elements of system 1050 may vary, depending on whether computing system 1050 is used as a stationary computing device (e.g., a server computer in a data center, a workstation, a desktop computer, etc.) or a mobile computing device (e.g., a smartphone, tablet computing device, laptop computer, game console, IoT device, etc.). In various implementations, the computing device system 1150 may comprise one or more components of a data center, a desktop computer, a workstation, a laptop, a smartphone, a tablet, a digital camera, a smart appliance, a smart home hub, a network appliance, and/or any other device/system that processes data.

The techniques described herein can be performed partially or wholly by software or other instructions provided in a machine-readable storage medium (e.g., memory). The software is stored as processor-executable instructions (e.g., instructions to implement any other processes discussed herein). Instructions associated with the flowchart (and/or various embodiments) and executed to implement embodiments of the disclosed subject matter may be implemented as part of an operating system or a specific application, component, program, object, module, routine, or other sequence of instructions or organization of sequences of instructions.

The storage medium can be a tangible, non-transitory machine readable medium such as read only memory (ROM), random access memory (RAM), flash memory devices, floppy and other removable disks, magnetic storage media, optical storage media (e.g., Compact Disk Read-Only Memory (CD ROMS), Digital Versatile Disks (DVDs)), among others.

The storage medium may be included, e.g., in a communication device, a computing device, a network device, a personal digital assistant, a manufacturing tool, a mobile communication device, a cellular phone, a notebook computer, a tablet, a game console, a set top box, an embedded system, a TV (television), or a personal desktop computer.

Some non-limiting examples of various embodiments are presented below.

Example 1 includes an apparatus, comprising: a finite state machine; a logic circuit coupled to the FSM; a tunable delay circuit having an input coupled to an output of the logic circuit, wherein the tunable delay circuit is also coupled to the FSM; a flip-flop having clock input coupled to the input of the tunable delay circuit and a data input coupled to an output of the tunable delay circuit; a first sampling circuit having a data input coupled to a data output of the flip-flop, a data output coupled to the FSM and a clock input coupled to the FSM; and a second sampling circuit having a data input coupled to the data output of the flip-flop, a data output coupled to the FSM and a clock input coupled to the FSM.

Example 2 includes the apparatus of Example 1, wherein the first and second sampling circuits comprise respective flip-flops.

Example 3 includes the apparatus of Example 1 or 2, wherein the FSM is to repeatedly adjust a delay of the tunable delay circuit in multiple iterations of a control loop based on data received from the data outputs of the first and second sampling circuits.

Example 4 includes the apparatus of Example 3, wherein the FSM is to provide a duty cycle adjustment signal to a clock generator of a clock signal received by the FSM based on an amount of the delay after the multiple iterations of the control loop, and the duty cycle adjustment signal indicates whether to increase or decrease a duty cycle.

Example 5 includes the apparatus of any one of Examples 1-4, wherein: the flip-flop is a first flip-flop; the logic circuit comprises a second flip-flop having a data input and a clock input coupled to the FSM to receive an inverted version of a clock signal and a third flip-flop having a data input and a clock input coupled to the FSM to receive a non-inverted version of the clock signal; a first pulse at the input of the tunable delay circuit is based on a transition in an output of the second flip-flop and a subsequent transition in an output of the third flip-flop; and a second pulse at the input of the tunable delay circuit is based on a transition in the output of the third flip-flop and a subsequent transition in the output of the second flip-flop.

Example 6 includes the apparatus of Example 5, wherein the logic circuit further comprises an AND gate having an input coupled to outputs of the second and third flip-flops and an output coupled to an input of the tunable delay circuit.

Example 7 includes the apparatus of Example 5 or 6, further comprising a sideload coupled to an output of at least one of the second or third flip-flops.

Example 8 includes the apparatus of any one of Examples 1-7, wherein: the first and second sampling circuits are to latch first and second bits, respectively, from the flip-flop; and the FSM is to adjust a delay of the tunable delay circuit based on the first and second bits.

Example 9 includes the apparatus of Example 8, wherein the FSM is to obtain multiple instances of the first and second bits from the first and second sampling circuits, respectively, and to adjust the delay with a varying gain based on the multiple instances of the first and second bits.

Example 10 includes the apparatus of any one of Examples 1-9, further comprising a duty cycle evaluation circuit which includes the FSM, the logic circuit, the tunable delay circuit, the flip-flop, the first sampling circuit and the second sampling circuit, wherein the duty cycle evaluation circuit is provided in at least one of an integrated circuit, a System on Chip, a System in Package or a computing device.

Example 11 includes a non-transitory machine-readable storage including machine-readable instructions that, when executed, cause a processor or other circuit to: receive a clock signal; control a logic circuit to output first and second pulses to a tunable delay buffer, wherein the first pulse has a transition of a first polarity which is based on a same-polarity transition of a first clock pulse of the clock signal, and the second pulse has a transition of the first polarity which is based on an opposite-polarity transition of a second clock pulse of the clock signal; receive first and second bits from a flip-flop coupled to the tunable delay buffer, wherein the first bit is obtained by sampling the flip-flop after the flip-flop latches a delayed version of the first pulse which is output from the tunable delay buffer and the second bit is obtained by sampling the flip-flop after the flip-flop latches the delayed version of the second pulse which is output from the tunable delay buffer; and adjust a delay of the tunable delay buffer based on the first and second bits.

Example 12 includes the non-transitory machine-readable storage of Example 11, wherein: when the first and second bits are 1 and 1, respectively, a delay of the tunable delay buffer is increased; and when the first and second bits are 0 and 0, respectively, a delay of the tunable delay buffer is decreased.

Example 13 includes the non-transitory machine-readable storage of Example 11 or 12, wherein the machine-readable instructions, when executed, further cause the processor or other circuit to: adjust the delay of the tunable delay buffer in multiple iterations of a control loop; and provide a duty cycle adjustment signal to a clock generator of the clock signal based on an amount of the delay after the multiple iterations of the control loop. Example 14 includes the non-transitory machine-readable storage of any one of Examples 11-13, wherein the adjusting of the delay comprises adjusting the delay with an initial gain and decreasing the gain when there is a switch in a polarity of the adjusting.

Example 15 includes the non-transitory machine-readable storage of any one of Examples 11-14, wherein the adjusting of the delay comprises adjusting the delay with an initial gain and increasing the gain when a polarity of the adjustment does not change after a threshold number of adjustments to the delay.

Example 16 includes an apparatus, comprising: a tunable delay circuit; a logic circuit coupled to an input of the tunable delay circuit; a flip-flop having a clock input coupled to the input of the tunable delay circuit and a data input coupled to an output of the tunable delay circuit; a sampling circuit coupled to an output of the flip-flop; and a control circuit coupled to the tunable delay circuit, the logic circuit, and the sampling circuit, wherein the control circuit is to input a clock signal to the logic circuit, the logic circuit in response to the clock signal is to input first and second pulses to the input of the tunable delay circuit, and the sampling circuit is to latch data from an output of the flip-flop indicating a duration of a high phase of the clock signal relative to a low phase of the clock signal.

Example 17 includes the apparatus of Example 16, wherein the flip-flop is falling edge triggered by the first and second pulses.

Example 18 includes the apparatus of Example 16 or 17, wherein the first pulse is initiated in response to a rising edge of one pulse of the clock signal and the second pulse is initiated in response to a falling edge of a next consecutive pulse of the clock signal.

Example 19 includes the apparatus of any one of Examples 16-18, wherein the control circuit is to decide whether to adjust a delay of the tunable delay circuit based on the latched data from the output of the flip-flop.

Example 20 includes the apparatus of Example 19, wherein the control circuit is to decide to not adjust the delay when latched data indicates a polarity of the adjusting has changed a threshold number of times.

Example 21 includes a method, comprising: receiving a clock signal; controlling a logic circuit to output first and second pulses to a tunable delay buffer, wherein the first pulse has a transition of a first polarity which is based on a same-polarity transition of a first clock pulse of the clock signal, and the second pulse has a transition of the first polarity which is based on an opposite-polarity transition of a second clock pulse of the clock signal; receiving first and second bits from a flip-flop coupled to the tunable delay buffer, wherein the first bit is obtained by sampling the flip-flop after the flip-flop latches a delayed version of the first pulse which is output from the tunable delay buffer and the second bit is obtained by sampling the flip-flop after the flip-flop latches the delayed version of the second pulse which is output from the tunable delay buffer; and adjusting a delay of the tunable delay buffer based on the first and second bits.

Example 22 includes a computer program comprising instructions which, when the program is executed by a computer, cause the computer to carry out the method of Example 21.

Example 23 includes an apparatus comprising means to perform the method of Example 21.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order than the described embodiment. Various additional operations may be performed and/or described operations may be omitted in additional embodiments.

The terms “substantially,” “close,” “approximately,” “near,” and “about,” generally refer to being within +/−10% of a target value. Unless otherwise specified the use of the ordinal adjectives “first,” “second,” and “third,” etc., to describe a common object, merely indicate that different instances of like objects are being referred to, and are not intended to imply that the objects so described have to be in a given sequence, either temporally, spatially, in ranking or in any other manner.

For the purposes of the present disclosure, the phrases “A and/or B” and “A or B” mean (A), (B), or (A and B). For the purposes of the present disclosure, the phrase “A, B, and/or C” means (A), (B), (C), (A and B), (A and C), (B and C), or (A, B, and C).

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

As used herein, the term “circuitry” may refer to, be part of, or include an Application Specific Integrated Circuit (ASIC), an electronic circuit, a processor (shared, dedicated, or group), a combinational logic circuit, and/or other suitable hardware components that provide the described functionality. As used herein, “computer-implemented method” may refer to any method executed by one or more processors, a computer system having one or more processors, a mobile device such as a smartphone (which may include one or more processors), a tablet, a laptop computer, a set-top box, a gaming console, and so forth.

The terms “coupled,” “communicatively coupled,” along with derivatives thereof are used herein. The term “coupled” may mean two or more elements are in direct physical or electrical contact with one another, may mean that two or more elements indirectly contact each other but still cooperate or interact with each other, and/or may mean that one or more other elements are coupled or connected between the elements that are said to be coupled with each other. The term “directly coupled” may mean that two or more elements are in direct contact with one another. The term “communicatively coupled” may mean that two or more elements may be in contact with one another by a means of communication including through a wire or other interconnect connection, through a wireless communication channel or link, and/or the like.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included. If the specification or claim refers to “a” or “an” element, that does not mean there is only one of the elements. If the specification or claims refer to “an additional” element, that does not preclude there being more than one of the additional elements.

Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

While the disclosure has been described in conjunction with specific embodiments thereof, many alternatives, modifications and variations of such embodiments will be apparent to those of ordinary skill in the art in light of the foregoing description. The embodiments of the disclosure are intended to embrace all such alternatives, modifications, and variations as to fall within the broad scope of the appended claims.

In addition, well-known power/ground connections to integrated circuit (IC) chips and other components may or may not be shown within the presented figures, for simplicity of illustration and discussion, and so as not to obscure the disclosure. Further, arrangements may be shown in block diagram form in order to avoid obscuring the disclosure, and also in view of the fact that specifics with respect to implementation of such block diagram arrangements are highly dependent upon the platform within which the present disclosure is to be implemented (i.e., such specifics should be well within purview of one skilled in the art). Where specific details (e.g., circuits) are set forth in order to describe example embodiments of the disclosure, it should be apparent to one skilled in the art that the disclosure can be practiced without, or with variation of, these specific details. The description is thus to be regarded as illustrative instead of limiting.

An abstract is provided that will allow the reader to ascertain the nature and gist of the technical disclosure. The abstract is submitted with the understanding that it will not be used to limit the scope or meaning of the claims. The following claims are hereby incorporated into the detailed description, with each claim standing on its own as a separate embodiment.

What is claimed is:

1. An apparatus, comprising:
a finite state machine (FSM);
a logic circuit coupled to the FSM;
a tunable delay circuit having an input coupled to an output of the logic circuit, wherein the tunable delay circuit is also coupled to the FSM;
a flip-flop having clock input coupled to the input of the tunable delay circuit and a data input coupled to an output of the tunable delay circuit;
a first sampling circuit having a data input coupled to a data output of the flip-flop, a data output coupled to the FSM and a clock input coupled to the FSM; and
a second sampling circuit having a data input coupled to the data output of the flip-flop, a data output coupled to the FSM and a clock input coupled to the FSM.

2. The apparatus of claim 1, wherein the first and second sampling circuits comprise respective flip-flops.

3. The apparatus of claim 1, wherein the FSM is to repeatedly adjust a delay of the tunable delay circuit in multiple iterations of a control loop based on data received from the data outputs of the first and second sampling circuits.

4. The apparatus of claim 3, wherein the FSM is to provide a duty cycle adjustment signal to a clock generator of a clock signal received by the FSM based on an amount of the delay after the multiple iterations of the control loop, and the duty cycle adjustment signal indicates whether to increase or decrease a duty cycle.

5. The apparatus of claim 1, wherein:
the flip-flop is a first flip-flop;
the logic circuit comprises a second flip-flop having a data input and a clock input coupled to the FSM to receive an inverted version of a clock signal and a third flip-flop having a data input and a clock input coupled to the FSM to receive a non-inverted version of the clock signal;
a first pulse at the input of the tunable delay circuit is based on a transition in an output of the second flip-flop and a subsequent transition in an output of the third flip-flop; and
a second pulse at the input of the tunable delay circuit is based on a transition in the output of the third flip-flop and a subsequent transition in the output of the second flip-flop.

6. The apparatus of claim 5, wherein the logic circuit further comprises an AND gate having an input coupled to outputs of the second and third flip-flops and an output coupled to an input of the tunable delay circuit.

7. The apparatus of claim 5, further comprising a sideload coupled to an output of at least one of the second or third flip-flops.

8. The apparatus of claim 1, wherein:
the first and second sampling circuits are to latch first and second bits, respectively, from the flip-flop; and
the FSM is to adjust a delay of the tunable delay circuit based on the first and second bits.

9. The apparatus of claim 8, wherein the FSM is to obtain multiple instances of the first and second bits from the first and second sampling circuits, respectively, and to adjust the delay with a varying gain based on the multiple instances of the first and second bits.

10. The apparatus of claim 1, further comprising a duty cycle evaluation circuit which includes the FSM, the logic circuit, the tunable delay circuit, the flip-flop, the first sampling circuit and the second sampling circuit, wherein the duty cycle evaluation circuit is provided in at least one of an integrated circuit, a System on Chip, a System in Package or a computing device.

11. A non-transitory machine-readable storage including machine-readable instructions that, when executed, cause a processor or other circuit to:
receive a clock signal;
control a logic circuit to output first and second pulses to a tunable delay buffer, wherein the first pulse has a transition of a first polarity which is based on a same-polarity transition of a first clock pulse of the clock signal, and the second pulse has a transition of the first polarity which is based on an opposite-polarity transition of a second clock pulse of the clock signal;
receive first and second bits from a flip-flop coupled to the tunable delay buffer, wherein the first bit is obtained by sampling the flip-flop after the flip-flop latches a delayed version of the first pulse which is output from the tunable delay buffer and the second bit is obtained by sampling the flip-flop after the flip-flop latches the delayed version of the second pulse which is output from the tunable delay buffer; and
adjust a delay of the tunable delay buffer based on the first and second bits.

12. The non-transitory machine-readable storage of claim 11, wherein:
when the first and second bits are 1 and 1, respectively, a delay of the tunable delay buffer is increased; and
when the first and second bits are 0 and 0, respectively, a delay of the tunable delay buffer is decreased.

13. The non-transitory machine-readable storage of claim 11, wherein the machine-readable instructions, when executed, further cause the processor or other circuit to:
adjust the delay of the tunable delay buffer in multiple iterations of a control loop; and
provide a duty cycle adjustment signal to a clock generator of the clock signal based on an amount of the delay after the multiple iterations of the control loop.

14. The non-transitory machine-readable storage of claim 11, wherein the adjusting of the delay comprises adjusting the delay with an initial gain and decreasing the gain when there is a switch in a polarity of the adjusting.

15. The non-transitory machine-readable storage of claim 11, wherein the adjusting of the delay comprises adjusting the delay with an initial gain and increasing the gain when a polarity of the adjustment does not change after a threshold number of adjustments to the delay.

16. An apparatus, comprising:
a tunable delay circuit;
a logic circuit coupled to an input of the tunable delay circuit;
a flip-flop having a clock input coupled to the input of the tunable delay circuit and a data input coupled to an output of the tunable delay circuit;
a sampling circuit coupled to an output of the flip-flop; and
a control circuit coupled to the tunable delay circuit, the logic circuit, and the sampling circuit, wherein the control circuit is to input a clock signal to the logic circuit, the logic circuit in response to the clock signal is to input first and second pulses to the input of the tunable delay circuit, and the sampling circuit is to latch data from an output of the flip-flop indicating a duration of a high phase of the clock signal relative to a low phase of the clock signal.

17. The apparatus of claim 16, wherein the flip-flop is falling edge triggered by the first and second pulses.

18. The apparatus of claim 16, wherein the first pulse is initiated in response to a rising edge of one pulse of the clock signal and the second pulse is initiated in response to a falling edge of a next consecutive pulse of the clock signal.

19. The apparatus of claim 16, wherein the control circuit is to decide whether to adjust a delay of the tunable delay circuit based on the latched data from the output of the flip-flop.

20. The apparatus of claim 19, wherein the control circuit is to decide to not adjust the delay when latched data indicates a polarity of the adjusting has changed a threshold number of times.
